(19) United States
(12) Patent Application Publication
(10) Pub. No.: US 2012/0063078 A1
(43) Pub. Date: Mar. 15, 2012

(54) MOTOR CONTROL MODULE

(76) Inventors: Mark J. Brudevold, Fridley, MN (US); Nicholas J. Stein, Rogers, MN (US); Peter E. Philen, Brooklyn Park, MN (US); Mark T. Weinberger, Mounds View, MN (US)

(21) Appl. No.: 13/321,587

(22) PCT Filed: May 28, 2010
(86) PCT No.: PCT/US10/36573

§ 371 Date: Nov. 21, 2011

Related U.S. Application Data
(60) Provisional application No. 61/181,779, filed on May 28, 2009.

(51) Int. Cl. H05K 7/00

(52) U.S. Cl. 361/679.02

(57) ABSTRACT

A control module 10 for an electric motor 34 is provided. Such motors 34, including DC brushless motors, are commonly used in many types of equipment including plural component proportioning equipment. The design includes four boards: a power conditioning module 12, a top board 14, a middle board 16 and a bottom board 18.

### TECHNICAL FIELD

This application claims the benefit of U.S. Application Ser. No. 61/181,779, filed May 28, 2009, the contents of which are hereby incorporated by reference.

1. Background Art

Various controls have been used for electric motors for many many years. Such motors, including DC brushless motors, are commonly used in many types of equipment including plural component proportioning equipment.

2. Disclosure of the Invention

It is an object of this invention to provide a motor control module which allows for efficient control, robustness with respect to temperature and vibration, versatility in controlling a variety of motors and which can be efficiently manufactured. The design includes four boards: a power conditioning module, a top board, a middle board, and a bottom board.

The top board is a universal motor control I/O board designed to work with any selection of middle and bottom boards for other motor types or power levels. Network/bus processor and network/bus common circuitry are included on this board.

The middle board is a controller for three-phase PWM to DC motors. dsPIC33 microprocessor technology is used and is designed to work with multiple varieties of bottom boards.

The bottom board is the power driver for three-phase PWM to DC motors. A Semikron six-pack IGBT (insulated gate bipolar transistor) module is used with International Rectifier drivers.

The power conditioning module accepts three-phase and single-phase power, stores energy in DC bus capacitors and outputs DC bus voltage.

The power conditioning and motor control modules plug directly together. A sheet metal cover, connector end-plates, token access door and machined heatsink are provided and the enclosure is designed to bolt next to motor in a servo-hydraulic system.

The system allows both three-phase and single-phase operation at full amperage. A custom inductor allows one motor control to be used on either single or three phase power.

MOVs are used for overvoltage protection and field-failure troubleshooting and a two-stage power filter in power conditioning module for optimized EMC performance is utilized. SVPWM output is provided to the PMSM motor. A software upgrade port is connected to both processors. An isolated power supply for motor control processor is powered by a low-voltage CAN network.

IP20 protection from live voltage is provided with the token access cover removed. The top board is scored to give IP20 protection in the enclosure and can be snapped off to fit in a different enclosure.

Other components include connector I/O for servo-hydraulic system, two RTDs, two pressure transducers, two digital I/O drivers (for solenoids), one analog I/O, one analog input designed specifically to support a linear transducer, one encoder connection (hall sensors, quadrature encoder, index pulse), two CAN connections, one memory token software upgrade port and one rotary selector switch

Diagnostics are provided which include alarms and advisories for amperage, voltage, IGBT temperature, communication failure. Power cutback is tied to IGBT temperature.

A data recording device stores power-up and advisory and alarm counter, IGBT and PCB temperature, voltage and motor output amps and can be used for diagnosis and review of warranty returns

Demagnetized motor detection is a key feature as this condition is difficult to trouble-shoot. The problem is often confused as an issue with the chemical or hydraulic pumps.

IGBT temperature monitoring and power cutback provides for maximum IGBT life. Operating outside of the temp spec has a huge impact on IGBT life. The cutback drops system performance, rather than simply shutting down the system.

A temperature isolation “chimney” around the custom inductor keeps heat away from capacitors

The enclosure design maximizes capacitor count, including polyoxymethylene sheets inside the cover which allow the capacitors to touch the cover without damaging them during high vibration testing.

A token port area is isolated with a foam block that prohibits access to high voltage areas of the motor control and prevents loss of the token if dropped.

Soft start limits the current into the capacitors, charging them slowly before allowing the relays to close which maximizes life of components.

These and other objects and advantages of the invention will appear more fully from the following description made in conjunction with the accompanying drawings wherein like reference characters refer to the same or similar parts throughout the several views.

### BRIEF DESCRIPTION OF DRAWINGS

FIG. 1 shows a perspective view of the motor control module of the instant invention.

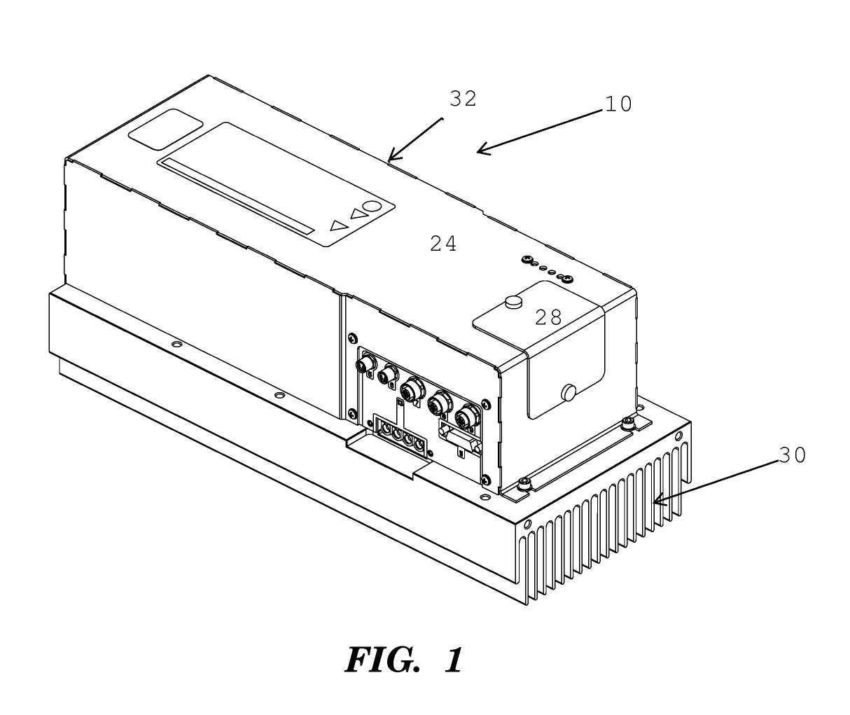

FIG. 2 shows a partially exploded perspective view of the motor control module of the instant invention.

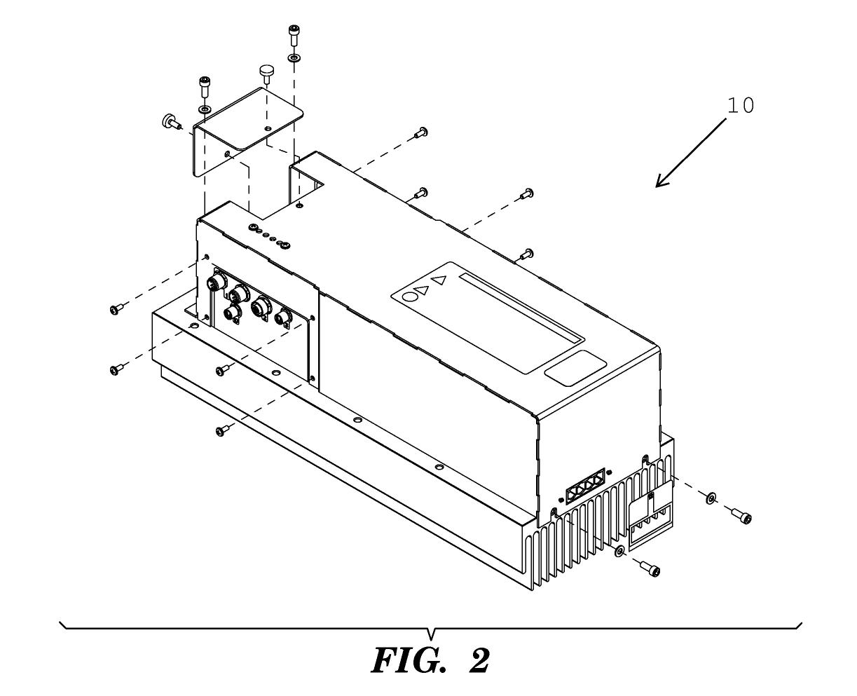

FIG. 3 shows another partially exploded perspective view of the motor control module of the instant invention.

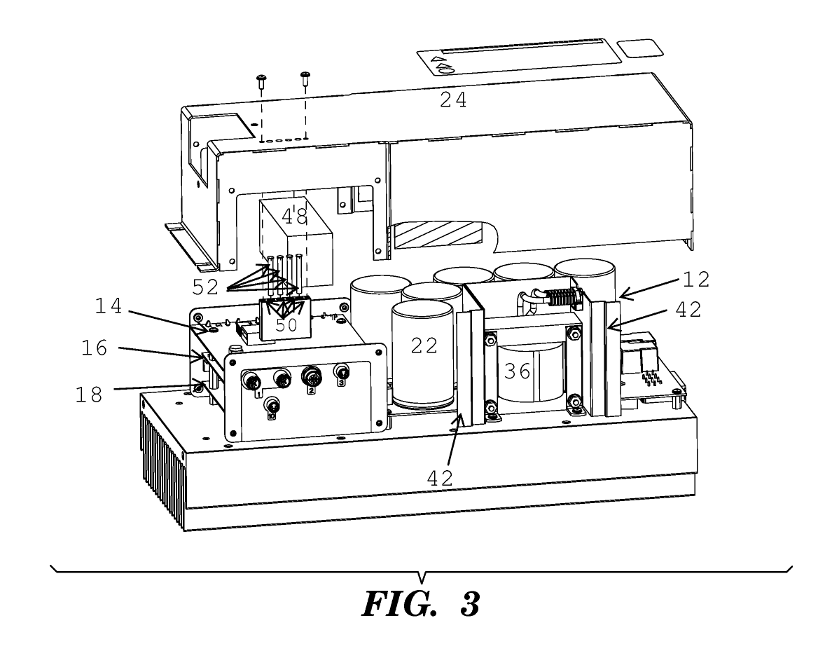

FIG. 4 shows a top view partially cutaway showing the LED area.

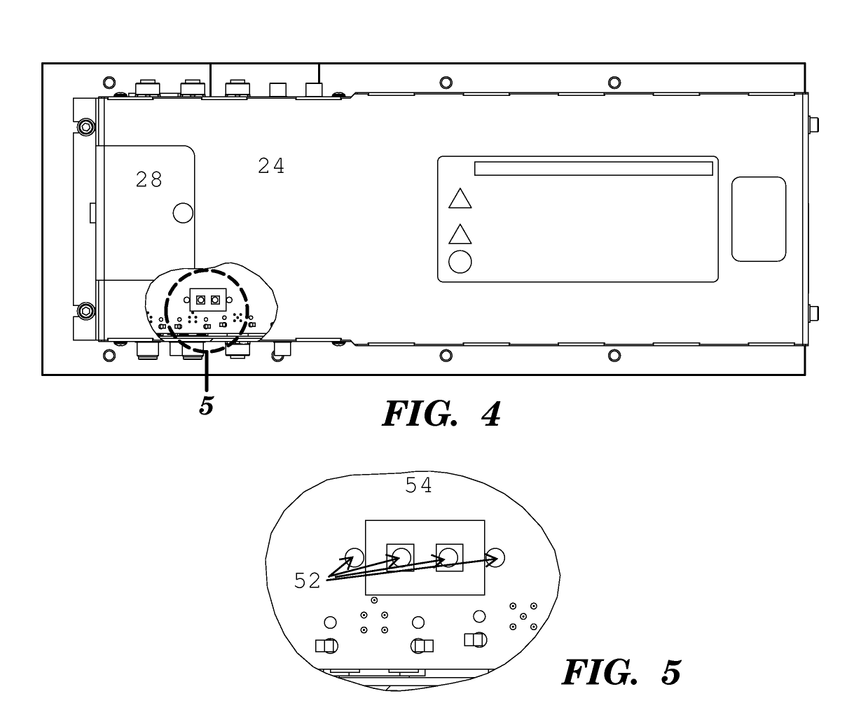

FIG. 5 shows the detail of the FIG. 4 cutaway.

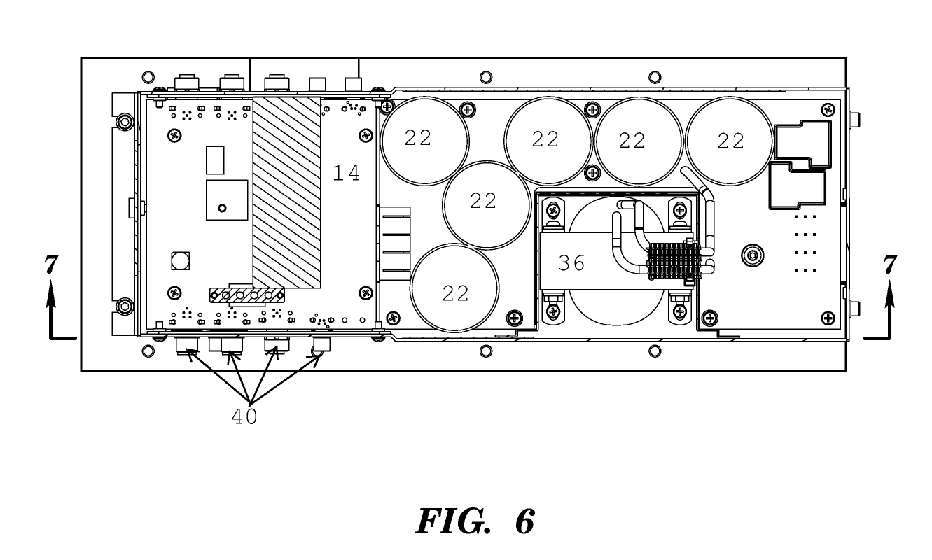

FIG. 6 shows a top view with the top removed.

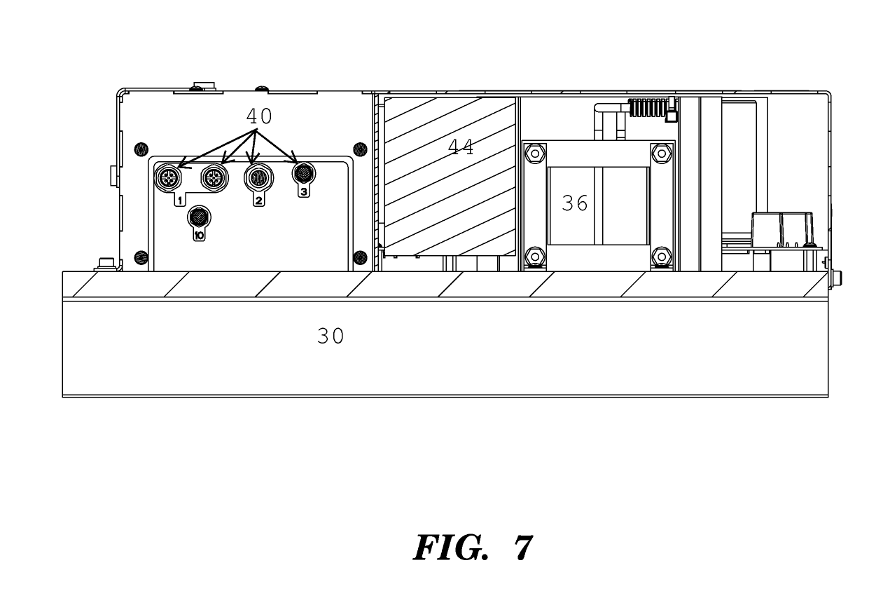

FIG. 7 shows a partially cutaway side view showing the insulating sheets.

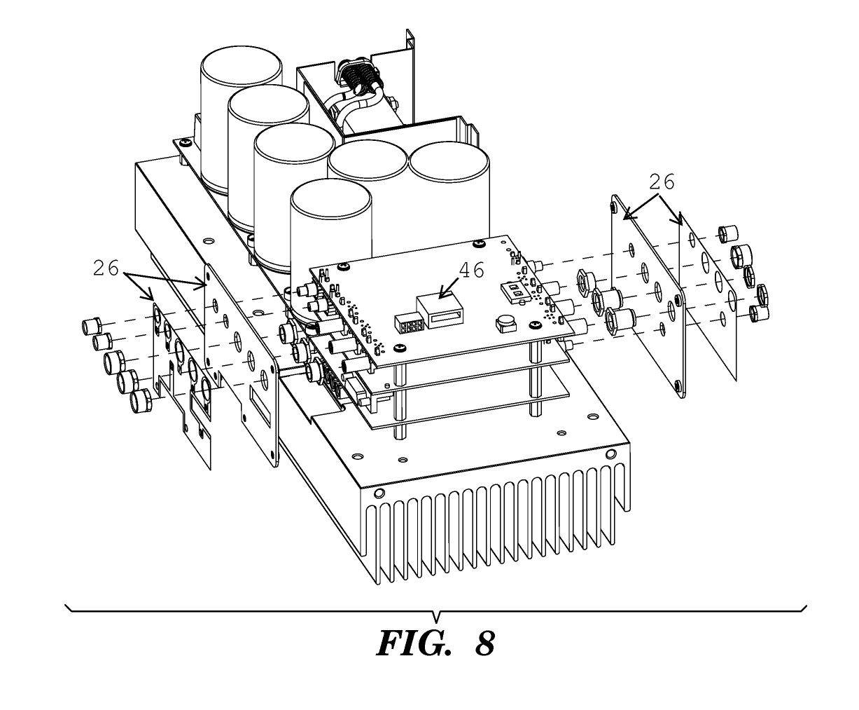

FIG. 8 is an exploded view.

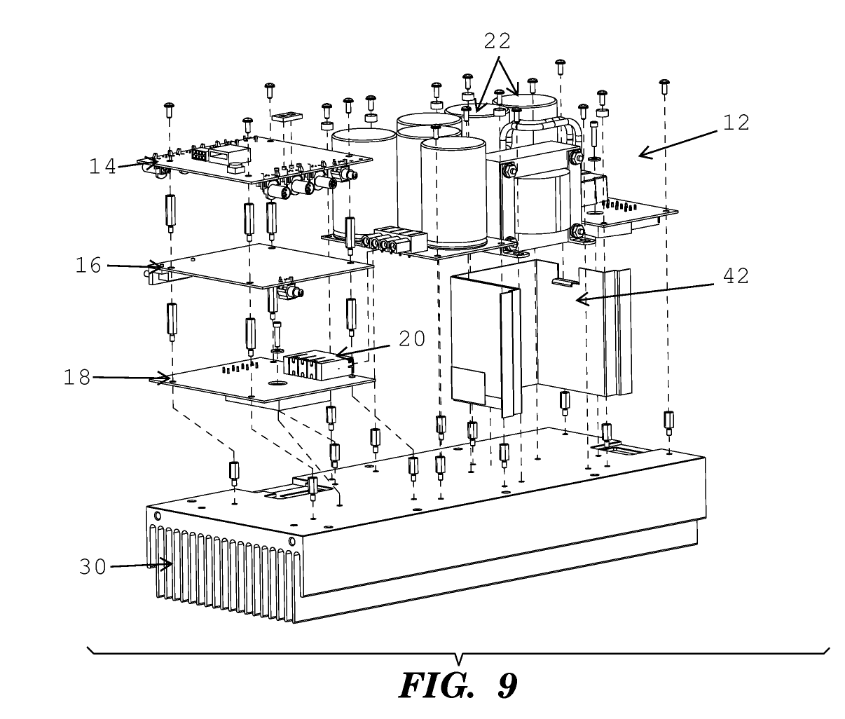

FIG. 9 is another exploded view.

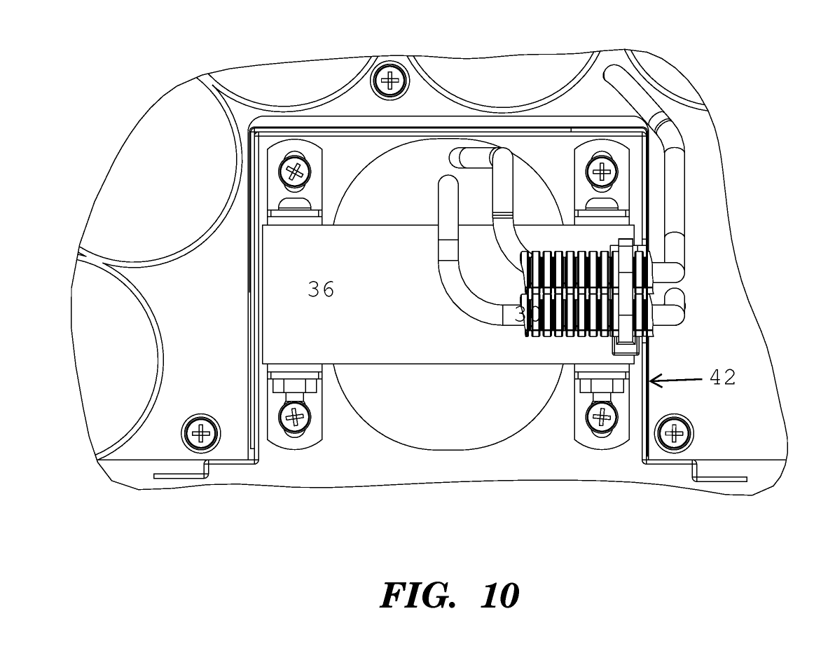

FIG. 10 is a detail view of the inductor and chimney.

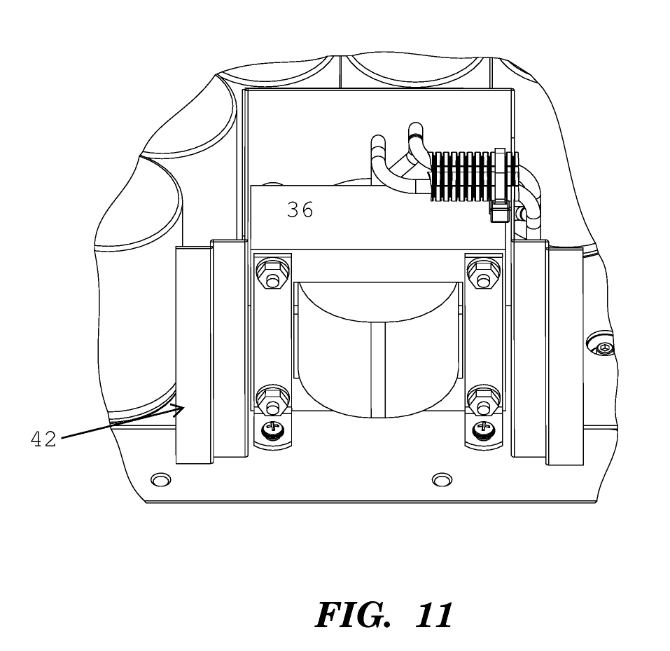

FIG. 11 is another detail view of the inductor and chimney

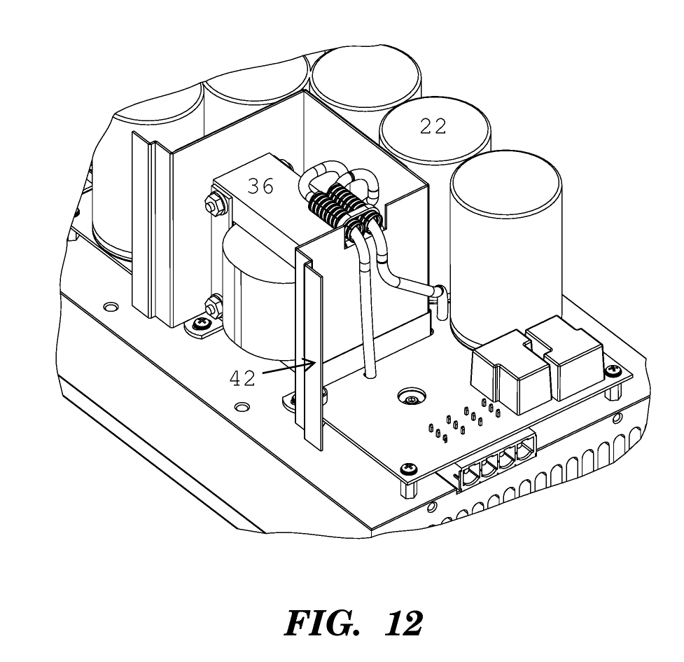

FIG. 12 is a partial detail view of the inductor and chimney

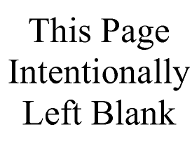

### BEST MODE FOR CARRYING OUT THE INVENTION

The motor control module of the instant invention is generally designated 10. The design includes four boards: a power conditioning module 12, a top board 14, a middle board 16, and a bottom board 18. The designations top, middle and bottom refer to the respective locations in the preferred embodiment and are used only for purpose of convenience. It is of course realized that alternative locations and orientations may be used if desired.

The top board 14 is a universal motor control I/O board designed to work with any selection of middle 16 and bottom 18 boards for other motor types or power levels. Network/bus processor and network/bus common circuitry are included on this board 14.

The middle board 16 is a controller for three-phase PWM to DC motors. dsPIC33 microprocessor technology is used and is designed to work with multiple varieties of bottom boards 18.

The bottom board 18 is the power driver for three-phase PWM to DC motors. A Semikron six-pack IGBT (insulated gate bipolar transistor) module 20 is used with International Rectifier drivers.

The power conditioning module 12 accepts three-phase and single-phase power, stores energy in DC bus capacitors 22 and outputs DC bus voltage.

The power conditioning 12 and motor control boards plug directly together. A sheet metal cover 24, connector end-plates 26, token access door 28 and machined heatsink 30 are provided and the enclosure 32 is designed to bolt next to motor 34 in a servo-hydraulic system.

The system allows both three-phase and single-phase operation at full amperage.

A custom inductor 36 allows one motor control to be used on either single or three phase power.

MOVs are used for overvoltage protection and field-failure troubleshooting and a two-stage power filter in power conditioning module for optimized EMC performance is utilized. SVPWM output is provided to the PMSM motor. A software upgrade port 38 is connected to both processors. An isolated power supply for motor control processor is powered by a low-voltage CAN network.

IP20 protection from live voltage is provided with the token access cover removed. The top board 14 is scored to give IP20 protection in the enclosure and can be snapped off to fit in a different enclosure.

Other components include connector I/O for servo-hydraulic system, two RTDs, two pressure transducers, two digital I/O drivers (for solenoids), one analog I/O, one analog input designed specifically to support a linear transducer, one encoder connection (hall sensors, quadrature encoder, index pulse), two CAN connections, one memory token software upgrade port and one rotary selector switch. The various I/O connections are collectively identified as 40.

Diagnostics are provided which include alarms and advisories for amperage, voltage, IGBT temperature, communication failure. Power cutback is tied to IGBT temperature.

A data recording device stores power-up and advisory and alarm counter, IGBT and PCB temperature, voltage and motor output amps and can be used for diagnosis and review of warranty returns.

Demagnetized motor detection is a key feature as this condition is difficult to trouble-shoot. The problem is often confused as an issue with the chemical or hydraulic pumps.

IGBT temperature monitoring and power cutback provides for maximum IGBT life. Operating outside of the temp spec has a huge impact on IGBT life. The cutback drops system performance, rather than simply shutting down the system.

A temperature isolation “chimney” 42 around the custom inductor 36 keeps heat away from capacitors 22.

The enclosure 32 design maximizes capacitor count, including polyoxymethylene sheets 44 inside the cover 24 which allow the capacitors 22 to touch the cover 24 without damaging them during high vibration testing.

A token port area 46 is isolated with a foam block 48 that prohibits access to high voltage areas of the motor control and prevents loss of the token if dropped.

LEDs 50 are provided for diagnostic purposes and are provided with tubes 52 to transmit the light therefrom to the surface of cover 24. An isolating foam pad 54 prevents light from bleeding between the LEDs 50 and their respective tubes 52.

Soft start limits the current into the capacitors, charging them slowly before allowing the relays to close which maximizes life of components.

It is contemplated that various changes and modifications may be made to the motor control module without departing from the spirit and scope of the invention as defined by the following claims.

1. A motor control module for controlling a DC brushless motor, said module comprising:
a power conditioning module;
a top motor control I/O board;
a middle microprocessor PWM board; and
a bottom power driver board.

2. The motor control module of claim 1 wherein said top board further comprises a network/bus processor and network/bus common circuitry.

3. The motor control module of claim 1 wherein said bottom board further comprises an IGBT module.

4. The motor control module of claim 1 wherein said power conditioning module 12 further comprises DC bus capacitors and an inductor.

5. The motor control module of claim 4 wherein said power conditioning module 12 further comprises a chimney around said inductor.
